(19) United States
(12) Patent Application Publication
(10) Pub. No.: US 2002/0044075 A1
(43) Pub. Date: Apr. 18, 2002

(54) Wireless digital data-transmission path

(76) Inventor: Werner Bauer, Dingolshausen (DE)

Correspondence Address: COLLARD & ROE, P.C., 1077 Northern Boulevard, Roslyn, NY, 11576-1696, US

(21) Appl. No.: 09/927,450

(22) Filed: Aug. 10, 2001

(30) Foreign Application Priority Data
Aug. 10, 2000 (DE) 100 39 187.7

(51) Int. Cl. H03M 1/00; H04L 27/00

(52) U.S. Cl. 341/126; 375/259

(57) ABSTRACT

The invention relates to a digital data-transmission system, especially for transmission of digital audio data, with a transmitter (11) which receives a digital data stream to be transmitted and with a receiver which receives the transmitted digital data stream. According to the invention, it is provided that, upstream from the transmitter (11), there is connected a signal-processing circuit (12), which converts the signal shape of the digital data stream supplied thereto into a signal shape that can be transmitted loss-free by the transmitter (11).

### CROSS REFERENCE TO RELATED APPLICATIONS

Applicant claims priority under 35 U.S.C. §119 of German Application No. 100 39 187.7 filed Aug. 10, 2000.

### BACKGROUND OF THE INVENTION

1. Field of the Invention

The present invention relates to a digital data-transmission path, particularly for the transmission of digital audio data, with a transmitter which receives a digital data stream to be transmitted, and a receiver for receiving the transmitted digital data stream.

2. The Prior Art

In the past, this digital data-transmission path has been used, for example, to transmit the stereo signals from a source such as a CD player wirelessly to a headset. A disadvantage of prior-art data-transmission paths of this kind is that they do not permit a 1:1 data transmission, or in other words a high-loss data transmission. In this connection, data-reduction algorithms are used among other techniques in order to ensure operation in the available megahertz transmission region. Thus the known transmission paths have not been used for high-quality data transmission between, for example, a CD player and active speakers.

A further disadvantage of conventional digital data-transmission paths of the type cited above is that, due to limited bandwidth, they are restricted to the transmission of analog signals from the original two channels. In order to overcome the disadvantage of lossy data transmission, operation with more complex components have been designed, but these efforts have not been successful, because the associated costs are too high.

When analogue signals are transmitted by hardwire, multi-core arrangements are known in which, for example, analog signals are transmitted from a stage via microphones to a distant station, such as a recording and transmitting truck. This method of transmission of analog signals is subject to losses because the paths are relatively long, and must be spanned by cables. It is also costly, among other reasons because of the necessary local work for laying multicore cables.

An object of the present invention is to provide a digital data-transmission path which provides loss-free transmission of a digital data stream in an inexpensive design, in order to overcome the disadvantages of the prior art.

A further object of the present invention is to replace prior art multi-core arrangements inexpensively for loss-free signal transmission.

### SUMMARY OF THE INVENTION

Accordingly, the invention provides a signal-processing circuit which subjects the digital data stream to be transmitted to signal-shape conversion so that the converted digital data stream can be transmitted without problems, or in other words, loss-free by the transmitter. This data stream can be received without problems by the receiver, and then processed by the receiver arrangement. According to an advantageous alternative version, however, the original digital data stream is recovered at the receiving end providing a signal-processing circuit complementary to the transmitter arrangement in the receiver arrangement, in order to recover the original signal shape of this data stream in a 1:1 correspondence.

The inventive signal-processing circuit(s) can be achieved extremely inexpensively with conventional components so that the digital data-transmission path can be processed cost-effectively, since in all other respects it can also be based on a conventional cost-effective transmitter and a conventional cost-effective receiver.

The transmission frequency needed for the loss-free digital data transmission can be in the megahertz region. In order to make the data transmission and reception even more inherently immune from interference, the transmission frequency is selected in the gigahertz region. The gigahertz region has the added advantage that a much larger usable bandwidth is available, and therefore an even larger data stream can be transmitted than in the megahertz region.

The invention thus provides a loss-free data transmission with an inexpensive embodiment has not been possible heretofore because the signal shape of the digital data stream to be transmitted could not be processed loss-free by the transmitter (and by the receiver). Because the amplitude of the digital data stream was not optimally adapted to the transmitter (and receiver), and because in particular, the shape of the signal of the digital data stream, or in other words the pulse edges, were not adapted to the conditions of the transmitter. This disadvantage is overcome by the inventive signal-processing circuit in the transmitter arrangement. Moreover, due to the loss-free data transmission, the inventive transmission path is suitable for high-quality wireless transmissions of audio signals, for example to active speakers.

According to a particularly advantageous improvement of the invention, more than the two audio channels that have been transmittable heretofore can also be transmitted by the inventive digital data-transmission path, so that this transmission path represents an inexpensive and reliable, loss-free replacement for prior-art multiplex applications. A preferred embodiment of the digital transmission path both with regard to a transmitter and receiver arrangement, specifically using conventional components are available in an integrated and thus miniaturized space-saving form at low cost.

### BRIEF DESCRIPTION OF THE DRAWINGS

Other objects and features of the present invention will become apparent from the following detailed description considered in connection with the accompanying drawings. It should be understood, however, that the drawings are designed for the purpose of illustration only and not as a definition of the limits of the invention.

In the drawing, wherein similar reference characters denote similar elements throughout the several views:

FIG. 1 shows the transmitter arrangement of a preferred two-channel digital audio transmission path; and

FIG. 2 shows the receiver arrangement of the preferred two-channel digital audio transmission path.

### DETAILED DESCRIPTION OF PREFERRED EMBODIMENTS

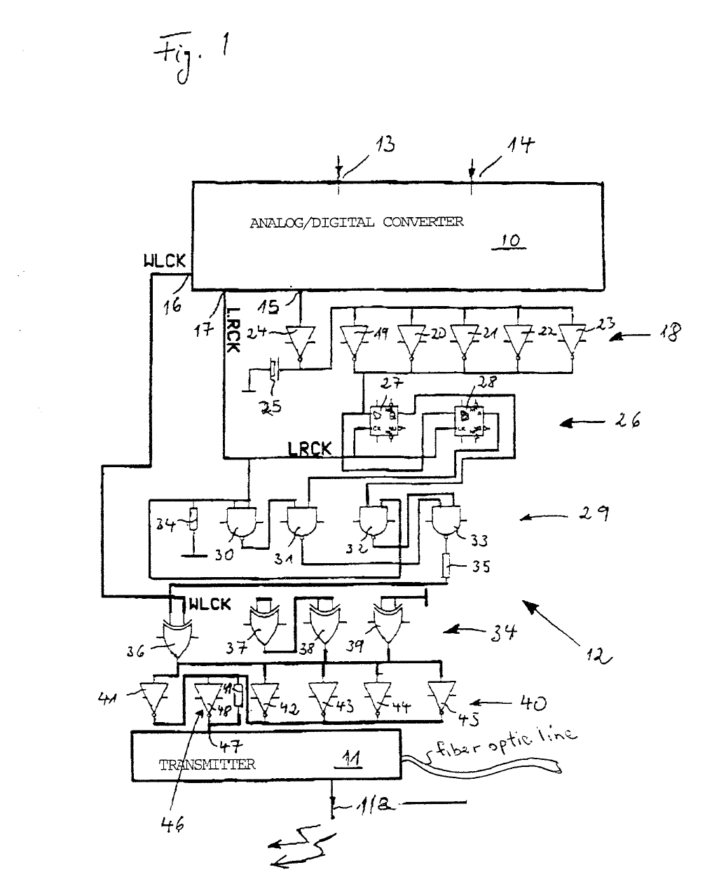

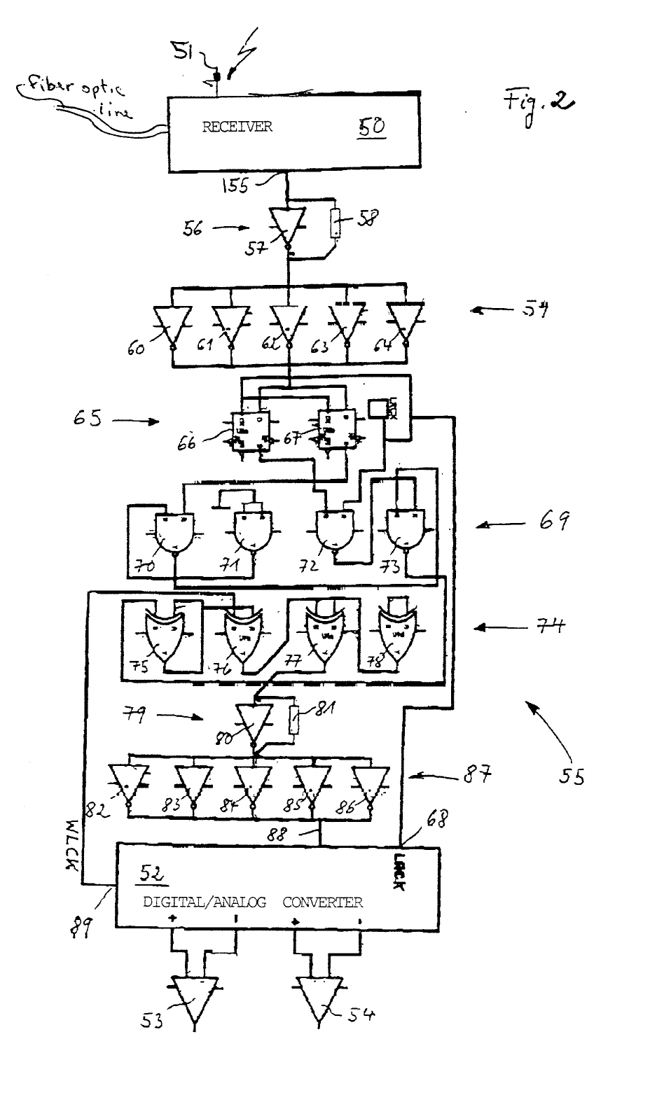

Turning now in detail to the drawings, the embodiment of a wireless digital data-transmission path shown in FIGS. 1 and 2 is designed as a two-channel transmission path, for example for the transmission of digital audio data. This digital transmission path is not limited to two channels, however, but it can be expanded without difficulty to 384 channels, for example, using currently available circuitry. Alternatively, the data can also be transmitted in an “unformatted” form, or in other words not organized in channels.

Referring to FIG. 1, the transmitter-end arrangement of the digital data-transmission path includes on the input side, an analog-to-digital converter (hereinafter A/D converter) 10 and on the output side a transmitter 11 for transmission of digital data. In order to transmit from transmitter 11, the full information content, the digital data stream at the output by A/D converter 10, to the receiver arrangement of FIG. 2, a signal-processing stage 12 is disposed between A/D converter 10 and transmitter 11, in order to condition the data stream output by A/D converter 10 so as to provide a loss-free data transmission to the receiver by means of transmitter 11.

A/D converter 10, is preferably a converter with a resolution of at least 24 bits, and a sampling frequency of at least 96 kilohertz, and used as a two-channel A/D converter. A/D converter 10 has two inputs 13 and 14 for receiving analog (stereo) signals. At output 15 of A/D converter 10, there is present a digital data stream, which constitutes a digital representation of the analog signals originally provided to inputs 13, 14 and which for example exists in S/PDIF format. Clock signals of the converter are present at two further outputs 16, 17 of A/D converter 10. In particular, a WLCK signal (where WLCK stands for word clock) is present at output 16, while an LRCK signal (where LRCK stands for left right clock) is present at output 17. The S/PDIF signal or the data stream at output 15 is characterized by a trapezoidal signal shape, and an amplitude of typically 0.5 volt. At least when transmitter 11 (and the corresponding receiver) is operated with a frequency in the gigahertz region (or alternatively in the MHz region) in order to ensure an adequate bandwidth for transmission of the digital data stream, it has been found that this signal shape cannot be processed and radiated loss-free via transmitter 11, and received loss-free by the receiver. In order to overcome this shortcoming, signal-processing circuit 12, is used and has as its input stage, a buffer circuit 18, which receives from inverter stage 24, the S/PDIF signal from output 15 of A/D converter 10. Buffer circuit 18 has five parallel-connected inverter stages 19 to 23. At the output side of inverter stage 24 is connected a quartz oscillator 25 to ground. The feedback effect of signal-processing circuit 12 on the A/D converter is suppressed by buffer circuit 18. Preferably, buffer circuit 18 has six inverter stages of an integrated hex inverter.

The output of buffer circuit 18 is followed in processing circuit 12 by an amplitude-processing circuit 26 in the form of a flip-flop circuit, or a dual flip-flop. The digital data stream at the output of buffer circuit 18 is injected into the D input of a first flip-flop 27 and into the D input of a second flip-flop 28. The clock inputs of two flip-flops 27 and 28 are connected to clock output 17 of A/D converter 10, which supplies the LRCK pulse. At the Q outputs of two flip-flops 27 and 28 there is provided the digital data stream that is present at the output of circuit 18, with an amplitude raised to TTL or HC level, namely to an amplitude of 3 volt. This data stream is injected into a NAND gate circuit 29.

NAND gate circuit 29 comprises four NAND gates 30, 31, 32 and 33. The two inputs of NAND gate 30 are connected in common to output 17 of A/D converter 10 and thus receive the LRCK pulse. Moreover, the two inputs of NAND gate 30 are connected to ground via a resistor 34. The output of NAND gate 30 is connected to one input of NAND gate 31, whose other input is connected to the Q output of flip-flop 28. The output of NAND gate 31 is connected to one input of NAND gate 33, whose other input is connected to the output of NAND gate 32. One output of NAND gate 32 is connected to the Q output of flip-flop 27 and the other input of NAND gate 32 is connected to output 17 of A/D converter 10, which controls the LRCK pulse signal. The output of NAND gate 33 forms the output of NAND gate circuit 29. At the output thereof there is a digital data stream, whose edges are steep compared with the original data stream at output 15 of the A/D converter. In particular, the data stream at the output of NAND gate circuit 29 is rectangular, whereas the signal shape of the output signal of the A/D converter is trapezoidal, as indicated in the foregoing.

To NAND gate circuit 29 there is connected an inverter circuit 34 for serial output of the digital data stream from NAND gate circuit 29. Inverter circuit 34 is connected via a resistor 35 to the output of NAND gate circuit 29. Specifically, inverter circuit 34 comprises four EXOR gates 36, 37, 38 and 39. One input of EXOR gate 36 is connected to the output of NAND gate circuit 29 via resistor 35, and the other input of EXOR gate 36 is connected to clock output 16 of A/D converter 10, which supplies the WLCK pulse signal. The output of EXOR gate 36 is connected to the output of EXOR gate 38 and to the output of EXOR gate 39, in order to apply these outputs in common to the output of inverter circuit 34. The two inputs of EXOR gate 37 are at positive supply voltage (5DVDD) for inverter circuit 34, and the output of EXOR gate 37 is connected to two inputs of EXOR gate 38. The two inputs of EXOR gate 39 are at ground.

The inverter circuit is followed by an output stage of buffer circuit 12 in the form of a buffer circuit 40, which is similar to buffer circuit 18, and has five buffer stages 41 to 45 connected in parallel. Buffer circuit 40 is connected on the input side to the output of inverter circuit 34, and on the output side to an amplitude-trimming circuit 46, which is connected on the output side to input 47 of transmitter 11. Amplitude-trimming circuit 46 comprises a buffer stage 48, whose input and output are bridged by means of a resistor 49. Buffer stages 41 to 45 and 48 can be the six buffer stages of a hex inverter.

Because of processing circuit 12 connected upstream, transmitter 11 is accordingly supplied with a digital data stream whose signal shape, derived from the original data-signal stream of D/A converter 10, is designed with amplitude and edge steepness so that this data stream can be transmitted without problems, and loss-free, by transmitter

Referring to FIG. 2, the receiver circuit has a receiver 50 with an antenna 51, which communicates wirelessly with an antenna 11a of transmitter 11. In an alternative embodiment, antennas 11a and 51 can be replaced by a fiber-optic transmission path.

Receiver 50 has on the output side a digital-to-analog converter (hereinafter D/A converter) 52, preferably with a resolution of at least 24 bits, and a sampling rate of at least 96 kHz. On the output side there are connected buffer/low-pass filter circuits 53 and 54, at the outputs of which there are present the recovered analog signals that were input into inputs 13 and 14 of A/D converter 10 in the transmitter arrangement of FIG. 1. Between receiver 50 and D/A converter 52 there is connected a signal-processing circuit 55, which in its signal-shaping portions, represents the complement of signal-processing circuit 12 in the transmitter arrangement of FIG. 1, and which otherwise has upstream and downstream buffer circuits similar to those of the circuit arrangement of FIG. 1.

Output 155 of receiver 50 is followed by an amplitude-trimming circuit 56 in the form of a buffer stage 57, whose input and output are bridged with a resistor 58. To amplitude-trimming circuit 56 there is connected a buffer circuit 59, which comprises five buffer stages 60 to 64 connected in parallel.

Buffer circuit 59 is followed by a flip-flop circuit 65 for recovery of the original signal amplitude of the digital data stream at output 15 of the A/D converter at the level of about 0.5 volt. This flip-flop circuit comprises two flip-flops 66 and 67. The D input of flip-flop 66 and the D input of flip flop 67 are connected to the output of the buffer circuit. The clock input of flip-flop 66 and the clock input of flip-flop 67 are connected to a clock output 68 of D/A converter 52, which supplies an LRCK signal. The Q output of flip-flop 66 and the Q output of flip-flop 67 are connected to a signal-processing circuit connected downstream from amplitude-processing circuit 65 and having the form of a NAND gate circuit 69, which comprises four NAND gates 70, 71, 72 and 73.

One input of NAND gate 70 is connected to the Q output of flip-flop 67. The other input of NAND gate 70 is connected to the output of NAND gate 71. The two inputs of NAND gate 71 are connected to ground (DGND). The output of NAND gate 70 is connected to one input of NAND gate 73. The other input of NAND gate 73 is connected to the output of NAND gate 72, whose one input is connected to the Q output of flip-flop 66, and whose other input is connected to clock output 68 of the D/A converter, which supplies the LRCK signal. The output of NAND gate 73 forms the output of NAND gate stage 69.

To NAND gate stage 69, which recovers the original edge steepness of the digital data stream at output 15 of A/D converter 10, there is connected an inverter circuit 74, which comprises four EXOR gates 75, 76, 77 and 78, and serves to output serially the data of the digital data stream from NAND gate circuit 69. One input of EXOR gate 75 is connected to its output and to one input of EXOR gate 76, while the other input of EXOR gate 75 is connected to the output of NAND gate circuit 69 (output of NAND gate 73). The other input of EXOR gate 76 is connected to a clock output 89 of D/A converter 52, which supplies a WRCK signal, while the output of EXOR gate 76 is connected to both inputs of EXOR gate 77 and to the output of EXOR gate 78. The two inputs of EXOR gate 78 are at positive supply voltage of inverter circuit 74. The output of EXOR gate 77 forms the output of inverter circuit 74.

The output of inverter circuit 74 is connected to an amplitude-trimming circuit 79, which includes a buffer stage 80. The input and output are bridged by means of a resistor 81, which forms part of an integrated hex inverter, whose other five buffer stages 82 to 86 form the parallel-connected stages of a buffer circuit 87. Buffer circuit 87 is connected between amplitude-trimming stage 79 and data-stream input 88 of D/A converter 52. Thus, at the input 88, there is the recovered digital data stream corresponding to the data stream at output 15 of A/D converter 10. In the illustrated practical example, this is an S/PDIF data stream, which can be converted without problems into analog signals by D/A converter 52.

In the invention, the transmission frequency is preferably 2.465 GHz or in another mode would be preferably 868 MHz.

While only a single embodiment of the present invention have been shown and described, it is to be understood that many changes and modifications may be made thereunto without departing from the spirit and scope of the invention as defined in the appended claims.

What is claimed is:

1. A digital data-transmission system for the transmission of digital audio data, comprising:
a transmitting arrangement comprising
a first signal processing circuit (12) coupled to the output of said analog/digital converter (10) for converting the signal shape of said digital data signals to a signal shape that can be transmitted loss-free;
a transmitter (11) coupled to the output of said first signal processing circuit (12) for transmitting the converted digital data signals; and,
a receiving arrangement for reconverting the data signals received from said transmitter (11).

2. The digital data-transmission system according to claim 1 wherein said receiving arrangement comprises:
a receiver (50), a second signal-processing circuit (55), coupled to the output of said receiver (50) for recovering from the received digital data signals, a digital data signal with a signal shape analogous to that of the original data signal of said transmitting arrangement.

3. The digital data-transmission system according to claim 2 wherein said transmitter (11) and said receiver (50) communicate wirelessly.

4. The digital data-transmission system according to claim 3 wherein said transmitter (11) and said receiver (50) communicate via a fiber optic line.

5. The digital data-transmission system according to claim 3 wherein said transmitter (11) and said receiver (50) communicate via antennas (11a, 51).

6. The digital data-transmission system according to claim 5 wherein said antennas (11a, 51) are directional radio antennas.

7. The digital data-transmission system according to claim 1 wherein the transmission frequency lies in the GHz region and in particular is 2.465 GHz.

8. The digital data-transmission system according to claim 7 wherein the transmission frequency lies in the MHz region and in particular is 868 MHz.

9. The digital data-transmission system according to claim 1 wherein the signal-shape processing comprises an amplitude processing.

10. The digital data-transmission system according to claim 9 wherein the signal amplitude is adapted to TTL level.

11. The digital data-transmission system according to claim 1 wherein said first signal processing circuit processes the signal edges of said digital data signals.

12. The digital data-transmission system according to claim 11 wherein said digital data signals are trapezoidal data-stream signals, wherein the steepness of the signal edges is increased.

13. The digital data-transmission system according to claim 12 wherein the data signal is converted into a rectangular signal.

14. The digital data-transmission system according to claim 2 wherein said first signal-processing circuit (12) at the transmitter end is clocked by a clock signal (WLCK, LRCK) of the original digital data signal.

15. The digital data-transmission system according to claim 1 wherein said second signal-processing circuit (55) at the receiver end is clocked by a clock (LRCK) of the digital data stream output.

16. The digital data-transmission system according to of claim 1 comprising an A/D converter (10) coupled as the input stage to said first signal processing circuit of said transmitting arrangement, wherein said first processing circuit (12) is clocked by clock signals (WLCK, LRCK) of said A/D converter (10).

17. The digital data-transmission system according to claim 16 wherein said first processing circuit (12) of said transmitting arrangement comprises a flip-flop circuit (26) for processing the amplitude of the digital data signals from said A/D converter (10) to said transmitter (11).

18. The digital data-transmission system according to claim 16 wherein said first processing circuit (12) at said transmitter end comprises a NAND gate circuit (29) for processing of the edge steepness of the digital data signal from said A/D converter (10) to said transmitter (11).

19. The digital data-transmission system according to claim 16 comprising a buffer circuit (18) connected to the output of said A/D converter (10).

20. The digital data-transmission system according to claim 17 wherein said first processing circuit (12) at said transmitting arrangement comprises an inverter circuit (34) coupled to its output for serial output of the data of the digital data signal from said signal-modification circuits (26, 29).

21. The digital data-transmission system according to claim 16 wherein said first processing circuit (12) at the transmitter end comprises a buffer circuit (40) as the output stage.

22. The digital data-transmission system according to claim 21 comprising an amplitude-trimming circuit (46) connected to the output of said buffer circuit (40).

23. The digital data-transmission system according to claim 16 comprising a D/A converter (52) as the output stage at the receiving arrangement wherein the signal processing function of said second processing circuit (55) of the receiver end is designed to be complementary to said first processing circuit (12) of said transmitting arrangement.

24. The digital data-transmission system according to claim 23 wherein said second processing circuit (55) of said receiving end arrangement is clocked by clock signals (LRCK) of said D/A converter (52).

25. The digital data-transmission system according to claim 23 wherein said second processing circuit (55) of said receiving arrangement comprises a flip-flop circuit (65) for recovery of the amplitude of the original digital data stream supplied by said A/D converter from the digital data signal supplied by said receiver (50).

26. The digital data-transmission system according to claim 23 wherein said second processing circuit (55) of said receiving arrangement comprises a NAND gate circuit (69) for recovery of the edge steepness of the original digital data signal from the digital data signal of said receiver (50).

27. The digital data-transmission system according to claim 23 comprising a buffer circuit (59) connected to the output of said receiver (50).

28. The digital data-transmission system according to claim 27 comprising an amplitude-trimming circuit (56) connected at the input of said buffer circuit (59).

29. The digital data-transmission system according to claim 23 wherein said second processing circuit (55) of said receiving arrangement comprises an inverter circuit (74), connected to the input of said D/A converter (52), for serial output of the data of the digital data signal.

30. The digital data-transmission system according to claim 23 wherein said second processing circuit (55) of said receiving arrangement comprises a buffer circuit (87) serving as the output stage.

31. The digital data-transmission system according to claim 30 comprising an amplitude-trimming circuit (79) connected to the input of said buffer circuit (87).

32. The digital data-transmission system according to claim 1 wherein the digital data signal is organized into a number of n>2 channels, in said transmitting arrangement, and multiplexed by means of a digital multiplexer on a bus system, which is interconnected to said first processing circuit (12) of said transmitting arrangement.
